(19) United States
(12) Patent Application Publication
(10) Pub. No.: US 2025/0176319 A1
(43) Pub. Date: May 29, 2025

(54) DISPLAY DEVICE, METHOD OF PROVIDING THE SAME, AND ELECTRONIC DEVICE INCLUDING THE SAME

(71) Applicant: Samsung Display Co., LTD., Yongin-si (KR)

(72) Inventors: Sukyeong Shin, Yongin-si (KR); JOON-HWA BAE, Yongin-si (KR); HEESUNG YANG, Yongin-si (KR); WOOJIN CHO, Yongin-si (KR)

(21) Appl. No.: 18/956,333

(22) Filed: Nov. 22, 2024

(30) Foreign Application Priority Data
Nov. 27, 2023 (KR) 10-2023-0166799

(51) Int. Cl. H01L 33/38; H01L 25/075; H01L 25/16; H01L 33/00; H01L 33/06

(52) U.S. Cl. CPC H10H 20/831; H01L 25/167; H10H 20/01; H10H 20/812; H01L 25/0753; H10H 20/032

(57) ABSTRACT

A display device includes a substrate, a via insulating layer on the substrate, a pixel electrode of a light emitting element, on the via insulating layer, the pixel electrode including in order from the via insulating layer a first pixel electrode layer, a second pixel electrode layer having an upper surface which is flat and a third pixel electrode layer.

This application claims priority to Korean Patent Application No. 10-2023-0166799 filed on Nov. 27, 2023, and all the benefits accruing therefrom under 35 U.S.C. § 119, the entire disclosure of which is incorporated by reference herein.

### BACKGROUND

### 1. Field

Embodiments relate to a display device and a method of manufacturing (or providing) the same.

### 2. Description of the Related Art

Various display devices such as an organic light emitting display device, a quantum dot display device, or the like include a plurality of layers such as an insulating layer, a metal layer, or the like stacked on a substrate. One or more of the plurality of layers may have surface irregularities.

### SUMMARY

Since surface irregularities of one or more layer within a stack of layers of a display device may be transferred to and affect adjacent layers, removing the surface irregularities may be performed on the stack of layers. For example, a polishing process such as chemical mechanical polishing (CMP) may be used to flatten surfaces of the plurality of layers or to remove step differences between the plurality of layers during a process of manufacturing (or providing) the display device.

Embodiments provide a display device with improved display quality.

Embodiments provide a method of manufacturing (or providing) the display device.

A display device according to an embodiment of the present disclosure includes a substrate, a via insulating layer on the substrate, a first pixel electrode on the via insulating layer, a second pixel electrode on the first pixel electrode and having an upper surface which is flat, and a third pixel electrode on the second pixel electrode.

In an embodiment, a thickness of the second pixel electrode may not be constant.

In an embodiment, the upper surface of the second pixel electrode may be polished to be flat (e.g., a polished surface).

In an embodiment, an upper surface of the via insulating layer may be polished to be flat (e.g., a polished surface).

In an embodiment, a thickness of the via insulating layer may not be constant.

In an embodiment, the display device may further include a light emitting layer on the third pixel electrode and including a quantum dot.

In an embodiment, the display device may further include a first active pattern on the substrate, and a second active pattern on the substrate, spaced apart from the first active pattern, and including a material different from the first active pattern.

A method of manufacturing (or providing) a display device according to an embodiment of the present disclosure includes forming (or providing) a via insulating layer on a substrate, forming a first pixel electrode layer on the via insulating layer, forming a second pixel electrode layer having an upper surface which is flat on the first pixel electrode layer, and forming a third pixel electrode layer on the second pixel electrode layer.

In an embodiment, the forming of the second pixel electrode layer may include forming a preliminary second pixel electrode layer having an upper surface of which a level is not constant on the first pixel electrode layer, and polishing the upper surface of the preliminary second pixel electrode layer to form the second pixel electrode layer.

In an embodiment, the forming of the second pixel electrode layer may be performed through a chemical mechanical polishing process.

In an embodiment, the forming of the second pixel electrode layer may be performed using a zirconia slurry.

In an embodiment, in the forming of the second pixel electrode layer, the upper surface of the preliminary second pixel electrode layer may be polished by a difference between a minimum level of the upper surface of the preliminary second pixel electrode layer and a maximum level of the upper surface of the preliminary second pixel electrode layer.

In an embodiment, the difference may be about 100 angstroms (Å) to about 5000 Å.

In an embodiment, the second pixel electrode layer may be formed to have a thickness which is not constant.

In an embodiment, after the forming of the third pixel electrode layer, the method may further include forming a pixel electrode by patterning the first pixel electrode layer, the second pixel electrode layer, and the third pixel electrode layer, and forming a light emitting layer on the pixel electrode.

In an embodiment, the light emitting layer may be formed through an inkjet process.

In an embodiment, the light emitting layer may include a quantum dot.

In an embodiment, the forming of the via insulating layer may include forming a preliminary via insulating layer having an upper surface of which a level is not constant on the substrate, and polishing the upper surface of the preliminary via insulating layer to form the via insulating layer having an upper surface which is flat.

In an embodiment, the via insulating layer may be formed to have a thickness which is not constant.

In an embodiment, the method may further include forming a first active pattern on the substrate, and forming a second active pattern spaced apart from the first active pattern and including a material different from the first active pattern on the substrate.

An electronic device according to an embodiment of the present disclosure includes a display device and a power module that supplies power to the display device. The display device includes a substrate, a via insulating layer on the substrate, a first pixel electrode on the via insulating layer, a second pixel electrode on the first pixel electrode and having an upper surface which is flat, and a third pixel electrode on the second pixel electrode.

In a display device according to embodiments of the present disclosure, the display device may include a pixel electrode including a first pixel electrode, a second pixel electrode whose upper surface is polished to be substantially flat, and a third pixel electrode. As a thickness of a light emitting layer on the pixel electrode may be substantially uniform without having a step difference, luminous efficiency and luminance uniformity of a light emitting element may be improved. In addition, as the upper surface of the second pixel electrode may be polished to provide a polished surface, a roughness of the second pixel electrode may be reduced, and thus a reflectance of the light emitting element may be improved. Accordingly, display quality of the display device may be improved.

### BRIEF DESCRIPTION OF THE DRAWINGS

FIG. 1 is a plan view illustrating a display device according to an embodiment of the present disclosure.

FIG. 2 is a cross-sectional view taken along line I-I′ of FIG. 1.

FIG. 3 is an enlarged cross-sectional view of area A of FIG. 2.

FIGS. 4, 5, 6, 7, 8, 9, 10, 11, and 12 are cross-sectional views illustrating a method of manufacturing (or providing) the display device of FIG. 2.

FIG. 13 is a cross-sectional view illustrating a display device according to an embodiment of the present disclosure.

FIG. 14 is an enlarged cross-sectional view of area E of FIG. 13.

FIGS. 15, 16, and 17 are cross-sectional views illustrating a method of manufacturing (or providing) the display device of FIG. 13.

FIG. 18 is a block diagram illustrating an electronic device according to an embodiment of the present disclosure.

FIG. 19 is a schematic view of electronic devices according to embodiments of the present disclosure.

### DETAILED DESCRIPTION

Hereinafter, embodiments of the present disclosure will be described in more detail with reference to the accompanying drawings. The same reference numerals are used for the same components in the drawings, and redundant descriptions of the same components will be omitted.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. For example, within the Figures and the text of the disclosure, a reference number indicating a singular form of an element may also be used to reference a plurality of the singular element.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

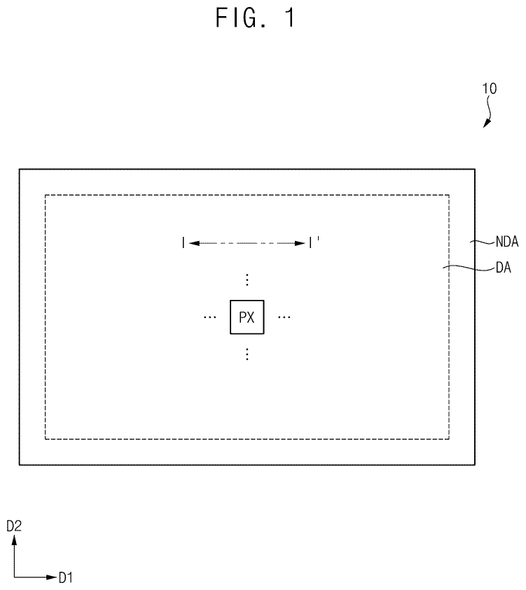

FIG. 1 is a plan view illustrating a display device 10 according to an embodiment of the present disclosure.

Referring to FIG. 1, a display device 10 may include a display area DA and a non-display area NDA.

A pixel PX provided in plural to define a plurality of pixels PX may be disposed in the display area DA. The plurality of pixels PX may be arranged in (or along) a first direction D1 and in (or along) a second direction D2 which intersects the first direction D1. For example, the first direction D1 may be perpendicular to the second direction D2. Each of the plurality of pixels PX may emit light. As each of the plurality of pixels PX may emit light, the display area DA may display an image using the emitted light.

Lines (e.g., signal lines, conductive lines, etc.) connected to the plurality of pixels PX may be further disposed in the display area DA. For example, the lines may include a data signal line, a gate signal line, a power line, or the like.

The non-display area NDA may be an area which does not display an image. The non-display area NDA may be located adjacent to the display area DA, such as being around the display area DA. For example, the non-display area NDA may surround the display area DA. The display area DA and the non-display area NDA may have a planar area defined along a plane defined by the first direction D1 and the second direction D2 crossing each other.

Drivers for driving the plurality of pixels PX may be disposed in the non-display area NDA. For example, the drivers may include a data driver, a gate driver, a power voltage generator, a timing controller, or the like. The plurality of pixels PX may emit light based on signals received from the drivers.

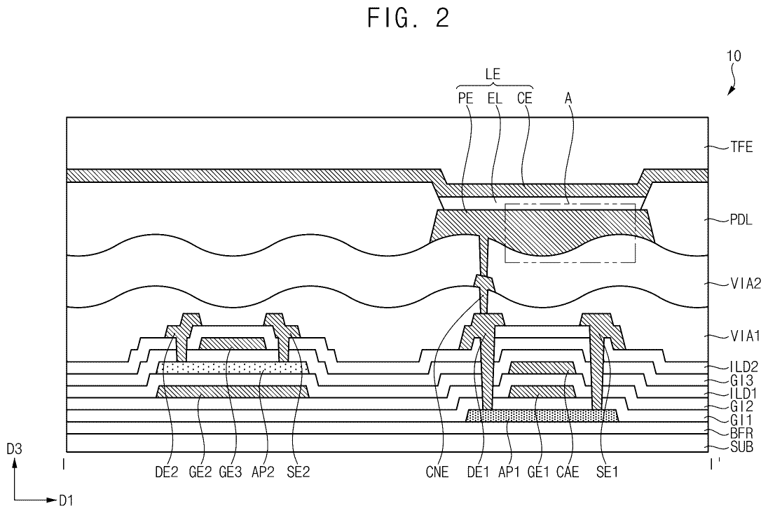

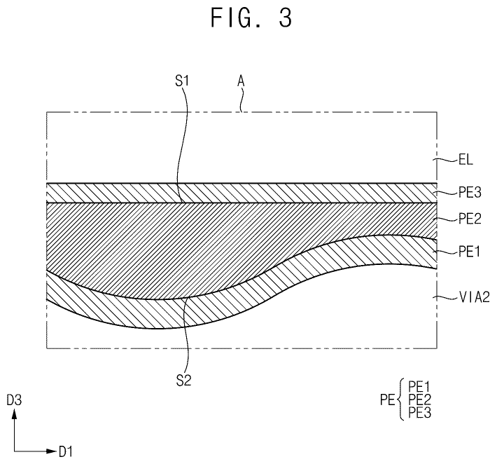

FIG. 2 is a cross-sectional view taken along line I-I′ of FIG. 1. FIG. 3 is an enlarged cross-sectional view of area A of FIG. 2. For example, FIG. 3 may be an enlarged cross-sectional view of a pixel electrode PE included in the display device 10.

Referring to FIGS. 1, 2, and 3, the display device 10 may include a substrate SUB, a buffer layer BFR, a plurality of insulating layers, a first active pattern AP1, a first gate layer, a second gate layer, a second active pattern AP2, a third gate layer, a first conductive layer, a second conductive layer, a light emitting element LE, a pixel defining layer PDL, and an encapsulation layer TFE.

The substrate SUB may include a transparent material or an opaque material. For example, the substrate SUB may include a rigid glass substrate, a plastic substrate, a flexible film, a metal substrate, or the like. These may be used alone or in combination with each other.

The buffer layer BFR may be disposed on the substrate SUB. The buffer layer BFR may prevent metal atoms or impurities from being diffused from the substrate SUB and into other layers within the stacked structure on the substrate SUB. In addition, when a surface of the substrate SUB is not uniform, the buffer layer BFR may improve a flatness of the surface of the substrate SUB on which the other layers are provided. The buffer layer BFR may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The first active pattern AP1 may be disposed on the buffer layer BFR. The first active pattern AP1 may include a source area, a drain area, and a channel area between the source area and the drain area. In an embodiment, the first active pattern AP1 may include a silicon semiconductor material. Examples of the silicon semiconductor material may include amorphous silicon, polycrystalline silicon, or the like. These may be used alone or in combination with each other.

A first gate insulating layer GI1 may be disposed on the buffer layer BFR and the first active pattern AP1. The first gate insulating layer GI1 may cover the first active pattern AP1. The first gate insulating layer GI1 may include an inorganic material such as silicon oxide, silicon nitride, silicon carbide, silicon oxynitride, silicon oxycarbide, or the like. These may be used alone or in combination with each other.

The first gate layer may be disposed on the first gate insulating layer GI1. The first gate layer may include a first gate electrode GE1. The first gate electrode GE1 may overlap the channel area of the first active pattern AP1 in a plan view. The first gate layer may include a metal, an alloy, a conductive metal oxide, a conductive metal nitride, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. Examples of the conductive metal nitride may include aluminum nitride (AlNₓ), tungsten nitride (WNₓ), chromium nitride (CrNₓ), or the like. These may be used alone or in combination with each other.

A second gate insulating layer GI2 may be disposed on the first gate insulating layer GI1 and the first gate layer. The second gate insulating layer GI2 may cover the first gate layer. The second gate insulating layer GI2 may include an inorganic material such as silicon oxide, silicon nitride, silicon carbide, silicon oxynitride, silicon oxycarbide, or the like. These may be used alone or in combination with each other.

The second gate layer may be disposed on the second gate insulating layer GI2. The second gate layer may include a capacitor electrode CAE and a second gate electrode GE2. The capacitor electrode CAE may overlap the first gate electrode GE1 in a plan view. For example, the capacitor electrode CAE and the first gate electrode GE1 may together define a storage capacitor. The second gate electrode GE2 may be spaced apart from the capacitor electrode CAE. The second gate layer may include a metal, an alloy, a conductive metal oxide, a conductive metal nitride, or the like. These may be used alone or in combination with each other.

The capacitor electrode CAE and the second gate electrode GE2 may be in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto

A first interlayer insulating layer ILD1 may be disposed on the second gate insulating layer GI2 and the second gate layer. The first interlayer insulating layer ILD1 may cover the second gate layer. The first interlayer insulating layer ILD1 may include an inorganic material such as silicon oxide, silicon nitride, silicon carbide, silicon oxynitride, silicon oxycarbide, or the like. These may be used alone or in combination with each other.

The second active pattern AP2 may be disposed on the first interlayer insulating layer ILD1. The second active pattern AP2 may include a source area, a drain area, and a channel area between the source area and the drain area. The second active pattern AP2 may be spaced apart from the first active pattern AP1, and may include a material different from the first active pattern AP1. However, the present disclosure is not limited thereto, and the second active pattern AP2 may include the same material as the first active pattern AP1. In an embodiment, the second active pattern AP2 may include an oxide semiconductor material. Examples of the oxide semiconductor material may include indium gallium zinc oxide, indium tin zinc oxide, or the like. These may be used alone or in combination with each other.

A third gate insulating layer GI3 may be disposed on the first interlayer insulating layer ILD1 and the second active pattern AP2. The third gate insulating layer GI3 may cover the second active pattern AP2. The third gate insulating layer GI3 may include an inorganic material such as silicon oxide, silicon nitride, silicon carbide, silicon oxynitride, silicon oxycarbide, or the like. These may be used alone or in combination with each other.

The third gate layer may be disposed on the third gate insulating layer GI3. The third gate layer may include a third gate electrode GE3. The third gate electrode GE3 may overlap the channel area of the second active pattern AP2 in a plan view. In addition, the third gate electrode GE3 may overlap the second gate electrode GE2 in a plan view. The third gate layer may include a metal, an alloy, a conductive metal oxide, a conductive metal nitride, or the like. These may be used alone or in combination with each other.

A second interlayer insulating layer ILD2 may be disposed on the third gate insulating layer GI3 and the third gate layer. The second interlayer insulating layer ILD2 may cover the third gate layer. The second interlayer insulating layer ILD2 may include an inorganic material such as silicon oxide, silicon nitride, silicon carbide, silicon oxynitride, silicon oxycarbide, or the like. These may be used alone or in combination with each other.

The first conductive layer may be disposed on the second interlayer insulating layer ILD2. The first conductive layer may include a first source electrode SE1, a first drain electrode DE1, a second source electrode SE2, and a second drain electrode DE2. The first conductive layer may include a metal, an alloy, a conductive metal oxide, a conductive metal nitride, or the like. These may be used alone or in combination with each other.

The first source electrode SE1 and the first drain electrode DE1 may be connected to the first active pattern AP1. For example, the first source electrode SE1 may be in contact with the source area of the first active pattern AP1, and the first drain electrode DE1 may be in contact with the drain area of the first active pattern AP1. In addition, the second source electrode SE2 and the second drain electrode DE2 may be connected to the second active pattern AP2. For example, the second source electrode SE2 may be in contact with the source area of the second active pattern AP2, and the second drain electrode DE2 may be in contact with the drain area of the second active pattern AP2. As being in contact, elements may be in physical contact such as to form an interface therebetween, without being limited thereto. Within the pixel circuit layer, a respective source electrode and a respective drain electrode may be connected (e.g., electrically connected) to a respective active pattern, such as within a switching element or transistor.

A first via insulating layer VIA1 may be disposed on the second interlayer insulating layer ILD2 and the first conductive layer. The first via insulating layer VIA1 may cover the first conductive layer. An upper surface of the first via insulating layer VIA1 may not be substantially flat due to a cross-sectional structure or profile defined by lower components (e.g., layers thereunder). That is, the upper surface of the first via insulating layer VIA1 may have a step difference, and a level of the upper surface of the first via insulating layer VIA1 may not be substantially constant. That is, a distance or height of the upper surface of the first via insulating layer VIA1, with respect to a reference like the upper surface of the substrate SUB, may be non-constant. The first via insulating layer VIA1 may include an organic material such as phenol resin, acrylic resin, polyimide resin, polyamide resin, siloxane resin, epoxy resin, or the like. These may be used alone or in combination with each other.

The second conductive layer may be disposed on the first via insulating layer VIA1. The second conductive layer may include a connection electrode CNE. The connection electrode CNE may be connected to the first drain electrode DE1 or the first source electrode SE1. For example, the connection electrode CNE may be in contact with the first drain electrode DE1 or the first source electrode SE1. The second conductive layer may include a metal, an alloy, a conductive metal oxide, a conductive metal nitride, or the like. These may be used alone or in combination with each other.

A second via insulating layer VIA2 may be disposed on the first via insulating layer VIA1 and the second conductive layer. The second via insulating layer VIA2 may cover the second conductive layer. The second via insulating layer VIA2 may have a single layer structure or a multilayer structure. An upper surface of the second via insulating layer VIA2 may not be substantially flat due to lower components. That is, the upper surface of the second via insulating layer VIA2 may have a step difference, and a level of the upper surface of the second via insulating layer VIA2 may not be substantially constant. The second via insulating layer VIA2 may include an organic material such as phenol resin, acrylic resin, polyimide resin, polyamide resin, siloxane resin, epoxy resin, or the like. These may be used alone or in combination with each other.

The light emitting element LE may be disposed on the second via insulating layer VIA2. The light emitting element LE may include the pixel electrode PE, a light emitting layer EL, and a common electrode CE. In an embodiment, the light emitting element LE of an image display layer may be connected to a pixel circuit layer providing electrical signals (e.g., a driving signal, a control signal, etc.) to the pixels PX. The pixel circuit layer may include a switching element, a transistor, a capacitor, and the like.

The pixel electrode PE may be disposed on the second via insulating layer VIA2. The pixel electrode PE may be connected to the connection electrode CNE. For example, the pixel electrode PE may be in contact with the connection electrode CNE. In an embodiment, an upper surface of the pixel electrode PE may be substantially flat. That is, the upper surface of the pixel electrode PE may not have a step difference, and a level of the upper surface of the pixel electrode PE from a reference, may be substantially constant. The pixel electrode PE may include a first pixel electrode PE1 as a first electrode layer, a second pixel electrode PE2 as a second electrode layer, and a third pixel electrode PE3 as a third electrode layer.

The first pixel electrode PE1 may be disposed on the second via insulating layer VIA2. The first pixel electrode PE1 may be disposed along a profile of the second via insulating layer VIA2. That is, an upper surface of the first pixel electrode PE1 may not be substantially flat and may have a cross-sectional profile corresponding to that of the upper surface of the first electrode layer. The first pixel electrode PE1 may include a conductive metal oxide. For example, the first pixel electrode PE1 may include indium tin oxide (ITO), but the present disclosure is not limited thereto.

The second pixel electrode PE2 may be disposed on the first pixel electrode PE1. In an embodiment, an upper surface S1 of the second pixel electrode PE2 may be substantially flat. That is, the upper surface S1 of the second pixel electrode PE2 which is a surface furthest from the substrate SUB may not have a step difference, and a level of the upper surface S1 of the second pixel electrode PE2 may be substantially constant. The second electrode layer planarizes the upper surface of the first electrode layer. For example, a material layer of the second electrode layer which has a non-uniform upper surface may be polished to define the upper surface S1 of the second pixel electrode PE2 which is substantially flat.

A lower surface S2 of the second pixel electrode PE2 which is a surface closest to the substrate SUB may be disposed along a profile of the first pixel electrode PE1 to have a shape corresponding thereto. Accordingly, the lower surface S2 of the second pixel electrode PE2 may not be substantially flat. That is, the lower surface S2 of the second pixel electrode PE2 may have a step difference, and a level of the lower surface S2 of the second pixel electrode PE2 may not be substantially constant.

In an embodiment, a thickness of the second pixel electrode PE2 may not be constant. Here, the thickness of the second pixel electrode PE2 may be a length (or dimension) of the second pixel electrode PE2 in a third direction D3 intersecting each of the first direction D1 and the second direction D2, to define a thickness direction. For example, the third direction D3 may be perpendicular to each of the first direction D1 and the second direction D2. As the lower surface S2 of the second pixel electrode PE2 may not be substantially flat and the upper surface S1 of the second pixel electrode PE2 may be substantially flat, the thickness of the second pixel electrode PE2 may not be uniform in a direction along the second via insulating layer VIA2. Here, within the pixel electrode PE, the first pixel electrode layer (e.g., the first pixel electrode PE1) has an uneven upper surface in a direction along the first pixel electrode layer, and a thickness of the second pixel electrode layer (e.g., the second pixel electrode PE2) is not constant in the direction along the first pixel electrode layer.

The second pixel electrode PE2 may include a metal as being a different material from the material of the first pixel electrode PE1. For example, the second pixel electrode PE2 may include silver, but the present disclosure is not limited thereto. In an embodiment, a roughness (e.g., like a surface roughness) of the upper surface S1 of the second pixel electrode PE2 may be less than or equal to about 1.4 nanometers (nm). Accordingly, a reflectance of the second pixel electrode PE2 may be improved by having the surface roughness disclosed herein.

The third pixel electrode PE3 may be disposed on the second pixel electrode PE2. The third pixel electrode PE3 may be disposed along a profile of the upper surface S1 of the second pixel electrode PE2. That is, an upper surface of the third pixel electrode PE3, in addition to a lower surface thereof, may be substantially flat. The third pixel electrode PE3 may include a conductive metal oxide as being a different material from the material of the second pixel electrode PE2. For example, the third pixel electrode PE3 may include indium tin oxide, but the present disclosure is not limited thereto.

The pixel defining layer PDL may be disposed on the second via insulating layer VIA2 and the pixel electrode PE. The pixel defining layer PDL may include a pixel opening defined therein. The pixel opening defined in the pixel defining layer PDL may expose at least a portion of the pixel electrode PE to outside the pixel defining layer PDL. For example, the pixel defining layer PDL may cover a side surface of the pixel electrode PE. The pixel defining layer PDL may include an organic material or an inorganic material.

The light emitting layer EL may be disposed on the pixel electrode PE. The light emitting layer EL may be disposed on an upper surface of the pixel electrode PE which is exposed to outside the pixel defining layer PDL by the pixel opening defined therein. As the upper surface of the pixel electrode PE is substantially flat, a thickness of the light emitting layer EL may be substantially constant. Here, the thickness of the light emitting layer EL may be a length of the light emitting layer EL in the third direction D3.

In an embodiment, the light emitting layer EL may include a quantum dot. The quantum dot may emit light by stimulation caused by light, and may improve color purity and color reproducibility. For example, the light emitting element LE may be a quantum dot light emitting element. The quantum dot may have a single structure with homogeneous component and composition or a composite structure such as a core-shell structure, a gradient structure, or the like. For example, the quantum dot may include a group II-VI semiconductor compound, a group III-VI semiconductor compound, a group III-V semiconductor compound, a group IV-VI semiconductor compound, a group IV element or compound, a group I-III-VI semiconductor compound, or the like. These may be used alone or in combination. However, the present disclosure is not limited thereto, and the light emitting layer EL may include an organic light emitting material, and the light emitting element LE may be an organic light emitting element.

Functional layers such as a hole injection layer, a hole transport layer, an electron transport layer, an electron injection layer, or the like may be disposed on or below the light emitting layer EL.

The common electrode CE may be disposed on the pixel defining layer PDL and the light emitting layer EL. The common electrode CE may include a metal, an alloy, a conductive metal oxide, a conductive metal nitride, a transparent conductive material, or the like. These may be used alone or in combination with each other. The common electrode CE may extend continuously across the plurality of pixels PX.

Accordingly, the light emitting element LE including the pixel electrode PE, the light emitting layer EL, and the common electrode CE may be disposed on the substrate SUB. The light emitting element LE may emit light in the third direction D3.

The encapsulation layer TFE may be disposed on the common electrode CE. The encapsulation layer TFE may protect the light emitting element LE from external oxygen and moisture. The encapsulation layer TFE may include at least one inorganic layer and at least one organic layer.

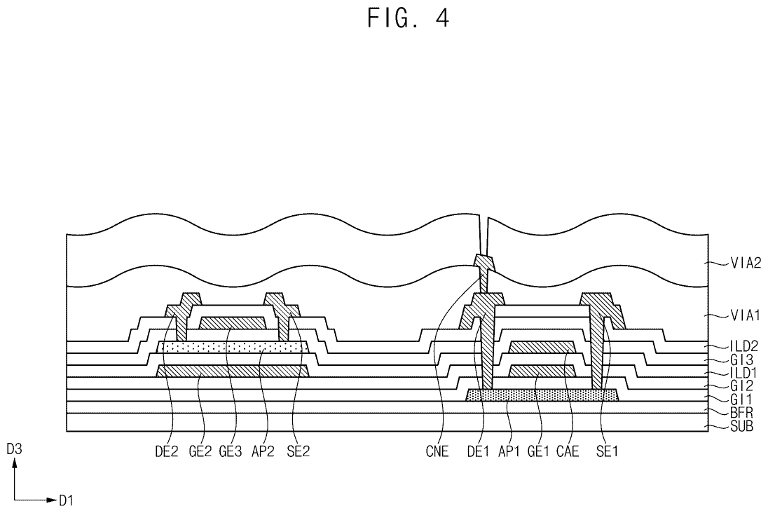

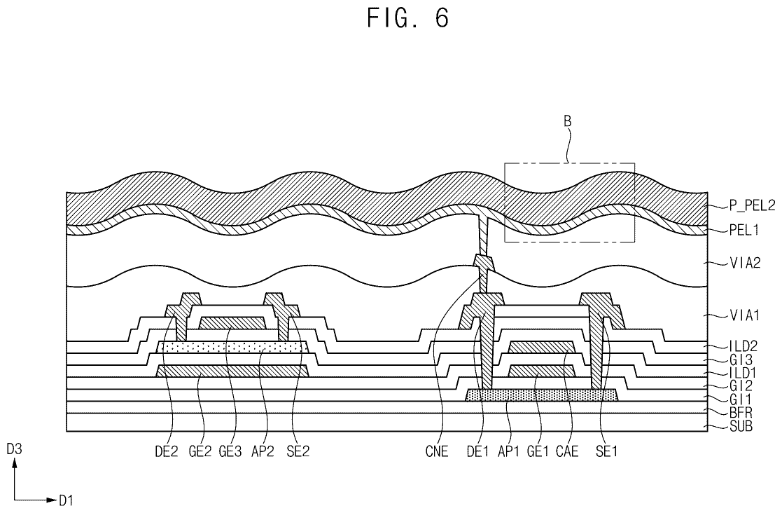

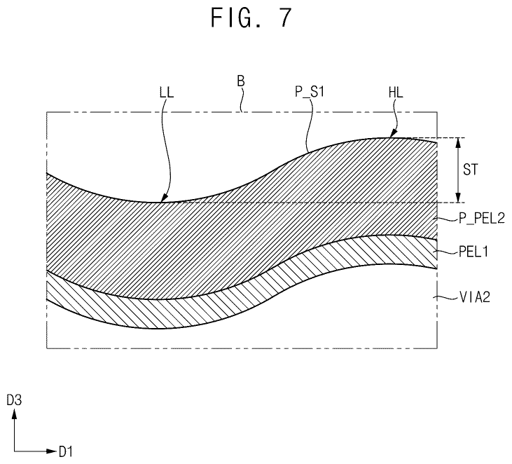

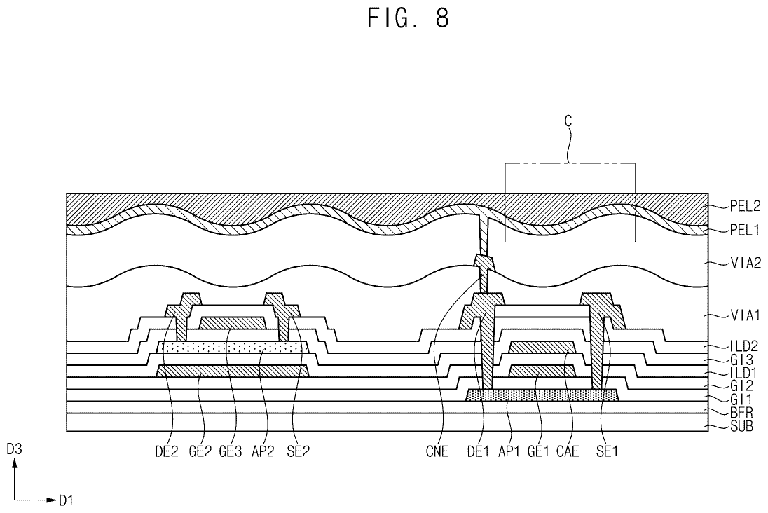

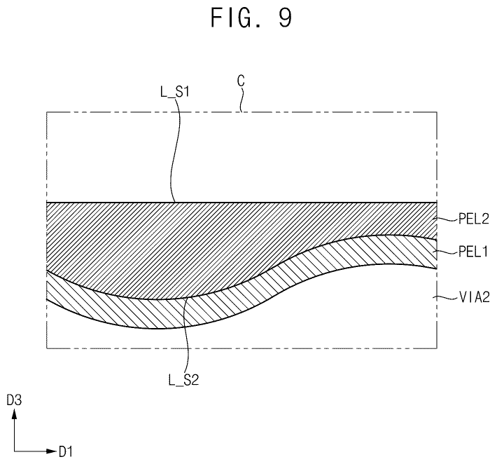

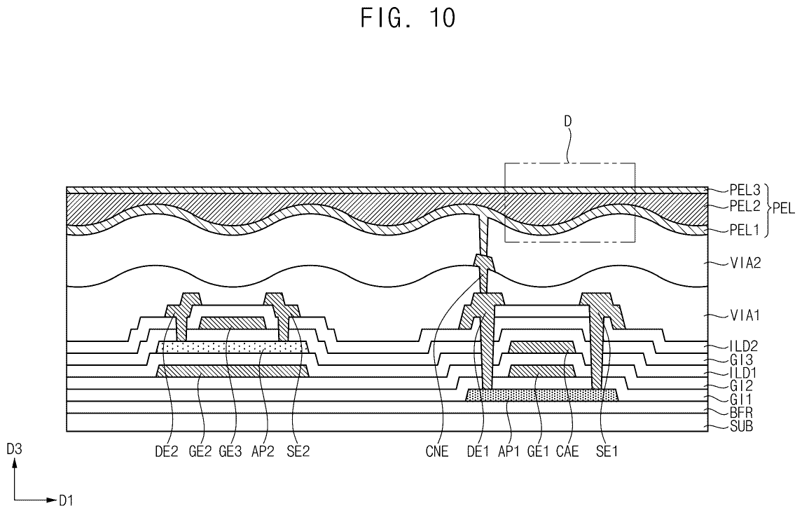

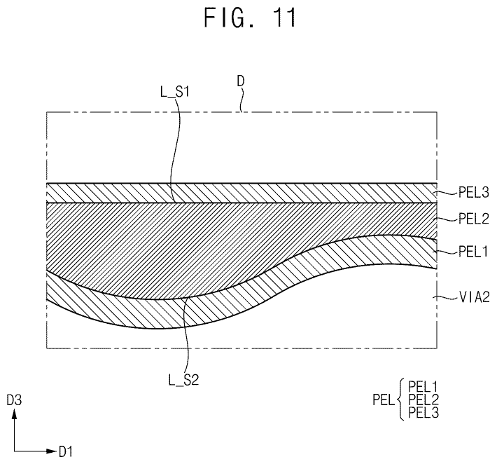

FIGS. 4, 5, 6, 7, 8, 9, 10, 11, and 12 are cross-sectional views illustrating a method of manufacturing (or providing) the display device 10 of FIG. 2. For example, FIG. 7 may be an enlarged cross-sectional view of area B of FIG. 6, FIG. 9 may be an enlarged cross-sectional view of area C of FIG. 8, and FIG. 11 may be an enlarged cross-sectional view of area D of FIG. 10.

A method of manufacturing (or providing) a display device 10 described with reference to FIGS. 4, 5, 6, 7, 8, 9, 10, 11, and 12 may be a method of manufacturing the display device 10 described with reference to FIGS. 1, 2, and 3. Accordingly, redundant descriptions will be omitted or simplified.

Referring to FIG. 4, the buffer layer BFR, the first active pattern AP1, the first gate insulating layer GI1, the first gate layer, the second gate insulating layer GI2, the second gate layer, the first interlayer insulating layer ILD1, the second active pattern AP2, the third gate insulating layer GI3, the third gate layer, the second interlayer insulating layer ILD2, the first conductive layer, the first via insulating layer VIA1, the second conductive layer, and the second via insulating layer VIA2 may be sequentially formed on the substrate SUB.

The upper surface of the second via insulating layer VIA2 may not be substantially flat. A contact hole which exposes at least a portion of the connection electrode CNE to outside the second via insulating layer VIA2 may be formed (or provided) in the second via insulating layer VIA2 at a location corresponding to a switching element (or a transistor).

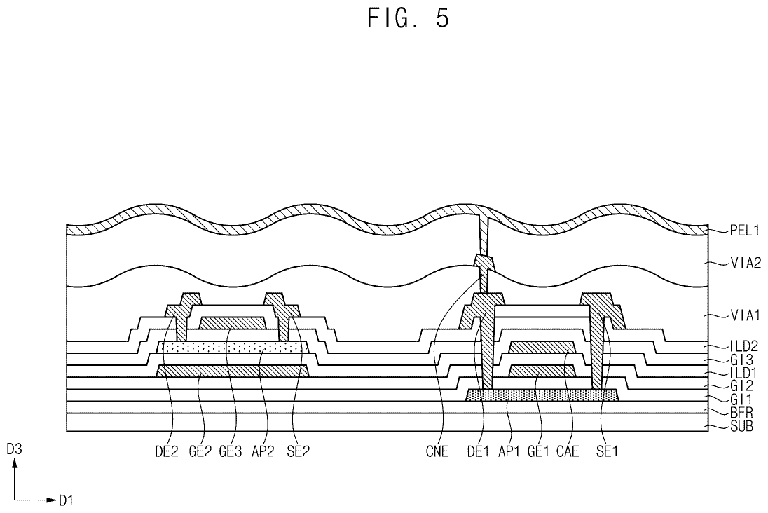

Referring to FIG. 5, a first pixel electrode layer PEL1 may be formed on the second via insulating layer VIA2. A material layer forming the first pixel electrode layer PEL1 may be formed along the profile of the second via insulating layer VIA2. That is, an upper surface of the first pixel electrode layer PEL1 provide by the material layer may not be substantially flat. The first pixel electrode layer PEL1 may be in contact with the connection electrode CNE through (or within) the contact hole formed in the second via insulating layer VIA2. The first pixel electrode layer PEL1 may include a conductive material such as a conductive metal oxide. For example, the first pixel electrode layer PEL1 may include indium tin oxide, but the present disclosure is not limited thereto.

Referring to FIGS. 6 and 7, a preliminary second pixel electrode layer P_PEL2 may be formed on the first pixel electrode layer PEL1. The material layer preliminarily forming the preliminary second pixel electrode layer P_PEL2 may be formed along a profile of the first pixel electrode layer PEL1. That is, a preliminary upper surface P_S1 of the preliminary second pixel electrode layer P_PEL2 may not be substantially flat. The preliminary upper surface P_S1 of the preliminary second pixel electrode layer P_PEL2 may have a step difference, and a level of the preliminary upper surface P_S1 of the preliminary second pixel electrode layer P_PEL2 relative to an underlying layer like the substrate SUB may not be substantially constant.

The preliminary upper surface P_S1 of the preliminary second pixel electrode layer P_PEL2 may include a minimum level LL at which the preliminary upper surface P_S1 is closest to the substrate SUB among locations along the substrate SUB, and a maximum level HL at which the preliminary upper surface P_S1 is furthest from the substrate SUB among locations along the substrate SUB. The minimum level LL (dotted line in FIG. 7) may be defined at a plane which is common to substantially an entirety of the the material layer. A lower thickness portion of the preliminary second pixel electrode layer P_PEL2 may be defined below the plane defined at the minimum level LL, while an upper thickness portion may be defined above the plane. The lower and upper thickness portions may meet at the plane.

For example, when the preliminary second pixel electrode layer P_PEL2 is formed, the upper thickness portion of the preliminary second pixel electrode layer P_PEL2 may be formed by a difference ST between a minimum level LL of the upper surface P_S1 of the preliminary second pixel electrode layer P_PEL2 and a maximum level HL of the upper surface P_S1 of the preliminary second pixel electrode layer P_PEL2. For example, when a thickness of an existing preliminary second pixel electrode layer P_PEL2 is about 800 angstroms (Å) and the difference ST is about 200 Å, the preliminary second pixel electrode layer P_PEL2 having a total thickness of about 1000 Å may be formed. That is, a total thickness may be defined from the maximum level HL and a lowermost position of the lower surface S2 (refer to FIG. 3) of the preliminary second pixel electrode layer P_PEL2. Here, the respective thicknesses of the preliminary second pixel electrode layer P_PEL2 may be a length (or height) of the preliminary second pixel electrode layer P_PEL2 in the third direction D3.

In an embodiment, the difference ST between the minimum level LL of the upper surface P_S1 of the preliminary second pixel electrode layer P_PEL2 and the maximum level HL of the upper surface P_S1 of the preliminary second pixel electrode layer P_PEL2 may be about 100 Å to about 5000 Å, but the present disclosure is not limited thereto.

Referring to FIGS. 7, 8, and 9, the upper surface P_S1 of the preliminary second pixel electrode layer P_PEL2 may be polished to form a second pixel electrode layer PEL2 having a flat upper surface. In an embodiment, the preliminary second pixel electrode layer P_PEL2 may be polished by the difference ST. That is, a total thickness of the preliminary second pixel electrode layer P_PEL2 is reduced to define the flat upper surface, where a reduced thickness corresponds to the different ST. Here, in the providing of the second pixel electrode layer, the uneven upper surface of the preliminary second pixel electrode layer P_PEL2 is polished to remove a thickness portion of the preliminary second pixel electrode layer P_PEL2 corresponding to the difference ST.

As the preliminary second pixel electrode layer P_PEL2 may be polished at the preliminary upper surface P_S1 thereof, a planarized upper surface L_S1 (or polished upper surface) of the second pixel electrode layer PEL2 may be substantially flat. That is, the planarized upper surface L_S1 of the second pixel electrode layer PEL2 may not have a step difference, and a level of the planarized upper surface L_S1 of the second pixel electrode layer PEL2 may be substantially constant with respect to a reference surface or reference plane.

For example, the preliminary upper surface P_S1 of the preliminary second pixel electrode layer P_PEL2 may be polished through a chemical mechanical polishing (CMP) process. In addition, the polishing process may be performed using a zirconia slurry, but the present disclosure is not limited thereto.

In an embodiment, a thickness of the second pixel electrode layer PEL2 at positions along the first pixel electrode layer PEL1 may not be constant. Here, the thickness of the second pixel electrode layer PEL2 may be a length of the second pixel electrode layer PEL2 in the third direction D3, at a corresponding position along the first pixel electrode layer PEL1. That is, as a lower surface L_S2 of the second pixel electrode layer PEL2 may be formed along a profile of the first pixel electrode layer PEL1 and the planarized upper surface L_S1 of the second pixel electrode layer PEL2 may be formed to be substantially flat through the polishing process, the thickness of the second pixel electrode layer PEL2 along the first pixel electrode layer PEL1 may not be uniform.

The second pixel electrode layer PEL2 may include a conductive material such as a metal. For example, the second pixel electrode layer PEL2 may include silver, but the present disclosure is not limited thereto. As the planarized upper surface L_S1 of the second pixel electrode layer PEL2 may be formed through the polishing process, a surface roughness of the planarized upper surface L_S1 of the second pixel electrode layer PEL2 may be reduced. For example, the roughness of the planarized upper surface L_S1 of the second pixel electrode layer PEL2 may be less than or equal to about 1.4 nm. Accordingly, a reflectance of the second pixel electrode layer PEL2 may be improved.

Referring to FIGS. 10 and 11, a third pixel electrode layer PEL3 may be formed on the second pixel electrode layer PEL2.

The third pixel electrode layer PEL3 may be disposed along a profile of the planarized upper surface L_S1 of the second pixel electrode layer PEL2. That is, an upper surface of the third pixel electrode layer PEL3 may be substantially flat. The third pixel electrode layer PEL3 may include a conductive metal oxide. For example, the third pixel electrode layer PEL3 may include indium tin oxide, but the present disclosure is not limited thereto. In an embodiment, the upper surface of the third pixel electrode layer PEL3 may be substantially flat owing to the planarized upper surface L_S1 of the second pixel electrode layer PEL2 along which a material layer for forming the third pixel electrode layer PEL3 is provided.

Accordingly, a pixel electrode layer PEL including the first pixel electrode layer PEL1, the second pixel electrode layer PEL2, and the third pixel electrode layer PEL3 may be formed on the second via insulating layer VIA2. An upper surface of the pixel electrode layer PEL may be substantially flat. The upper surface of the pixel electrode layer PEL may be coplanar with or parallel to a plane in which the minimum level LL (refer to FIG. 7) is defined.

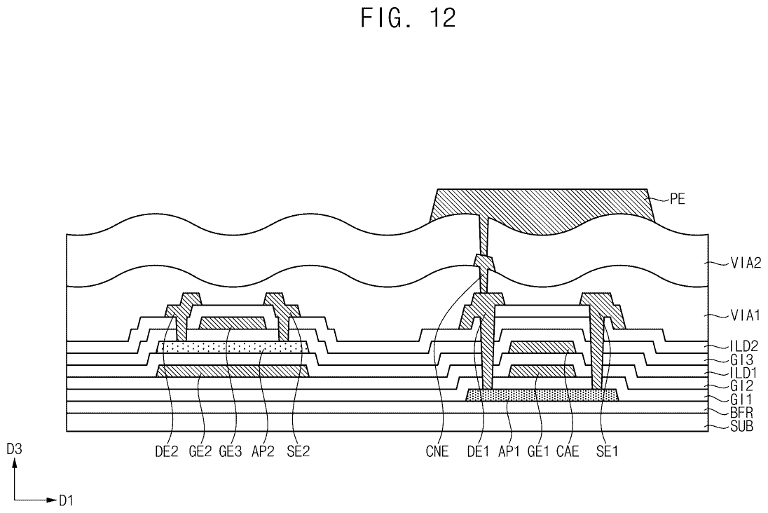

Referring to FIGS. 10 and 12, the pixel electrode layer PEL as a preliminary pixel electrode may be patterned to form the pixel electrode PE including patterned portions of each of the first pixel electrode layer PEL1, the second pixel electrode layer PEL2, and the third pixel electrode layer PEL3. That is, the first pixel electrode layer PEL1, the second pixel electrode layer PEL2, and the third pixel electrode layer PEL3 may be patterned to form the pixel electrode PE. The upper surface of the pixel electrode PE may be substantially flat.

Referring back to FIG. 2, the pixel defining layer PDL, the light emitting layer EL, the common electrode CE, and the encapsulation layer TFE may be sequentially formed on the pixel electrode PE.

In an embodiment, the light emitting layer EL may be formed through an inkjet process. In this case, as the upper surface of the pixel electrode PE may be substantially flat, the thickness of the light emitting layer EL may be substantially uniform. In an embodiment, the thickness of the light emitting layer EL may be substantially uniform owing to the flat upper surface of the pixel electrode PE along which a material layer for forming the light emitting layer EL is provided

The display device 10 according to an embodiment of the present disclosure may include the second pixel electrode PE2 whose upper surface S1 is planarized, such as by polishing, to be substantially flat. As the thickness of the light emitting layer EL disposed on the second pixel electrode PE2 may be substantially uniform without having a step difference owing to the flat upper surface of the pixel electrode PE, luminous efficiency and luminance uniformity of the light emitting element LE may be improved. In addition, as the upper surface S1 of the second pixel electrode PE2 may be polished, the roughness of the second pixel electrode PE2 may be reduced, and thus the reflectance of the light emitting element LE may be improved. Accordingly, display quality of the display device 10 may be improved.

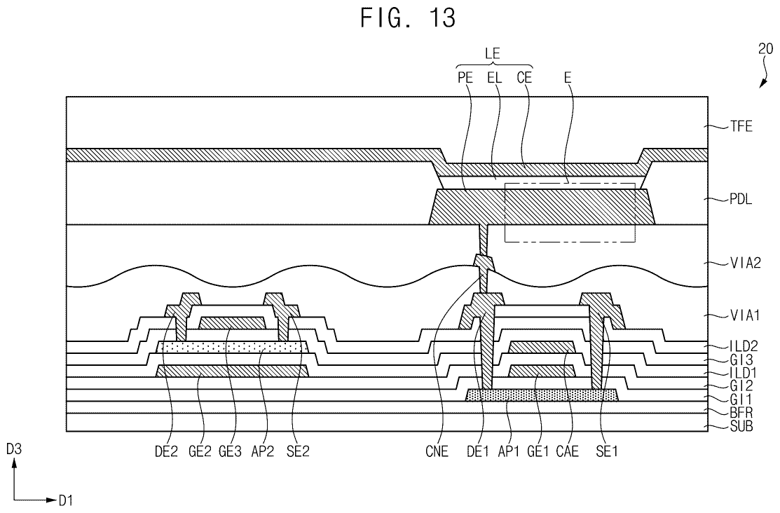

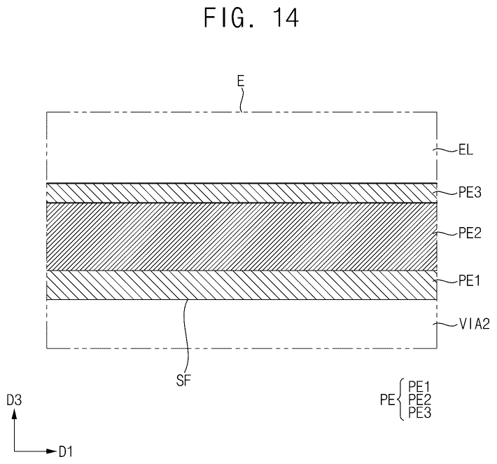

FIG. 13 is a cross-sectional view illustrating a display device 20 according to an embodiment of the present disclosure. FIG. 14 is an enlarged cross-sectional view of area E of FIG. 13. For example, FIG. 13 may be a cross-sectional view corresponding to the cross-sectional view of FIG. 2.

Hereinafter, descriptions overlapping the display device 10 described with reference to FIGS. 1, 2, and 3 will be omitted or simplified.

Referring to FIG. 13, a display device 20 may include a substrate SUB, a buffer layer BFR, a plurality of insulating layers, a first active pattern AP1, a first gate layer, a second gate layer, a second active pattern AP2, a third gate layer, a first conductive layer, a second conductive layer, a light emitting element LE, a pixel defining layer PDL, and an encapsulation layer TFE.

The buffer layer BFR, the first active pattern AP1, a first gate insulating layer GI1, the first gate layer, a second gate insulating layer GI2, the second gate layer, a first interlayer insulating layer ILD1, the second active pattern AP2, a third gate insulating layer GI3, the third gate layer, a second interlayer insulating layer ILD2, the first conductive layer, a first via insulating layer VIA1, and the second conductive layer may be sequentially disposed on the substrate SUB.

An upper surface of the first via insulating layer VIA1 may not be substantially flat due to lower components. That is, the upper surface of the first via insulating layer VIA1 may have a step difference, and a level of the upper surface of the first via insulating layer VIA1 may not be substantially constant.

A second via insulating layer VIA2 may be disposed on the first via insulating layer VIA1 and the second conductive layer. The second via insulating layer VIA2 may cover the second conductive layer. The second via insulating layer VIA2 may have a single layer structure or a multilayer structure. In an embodiment, an upper surface SF of the second via insulating layer VIA2 may be substantially flat. That is, the upper surface SF of the second via insulating layer VIA2 may not have a step difference, and a level of the upper surface SF of the second via insulating layer VIA2 may be substantially constant. For example, the upper surface SF of the second via insulating layer VIA2 may be polished to be substantially flat.

A lower surface of the second via insulating layer VIA2 may be disposed along an uneven profile of the first via insulating layer VIA1. Accordingly, the lower surface of the second via insulating layer VIA2 may not be substantially flat. That is, the lower surface of the second via insulating layer VIA2 may have a step difference, and a level of the lower surface of the second via insulating layer VIA2 may not be substantially constant. Here, at a location overlapping the pixel electrode PE, the via insulating layer includes a first via insulating layer VIA1 defining an uneven upper surface, a second via insulating layer VIA2 which is between the substrate SUB and the first pixel electrode layer, is closer to the pixel electrode PE than the first via insulating layer VIA1 and has an upper surface which is flat, and a thickness of the second via insulating layer VIA2 which is not constant in a direction along the pixel electrode PE.

In an embodiment, a thickness of the second via insulating layer VIA2 may not be constant at positions along the first via insulating layer VIA1. Here, the thickness of the second via insulating layer VIA2 may be a length of the second via insulating layer VIA2 in a third direction D3. As the lower surface of the second via insulating layer VIA2 may not be substantially flat and the upper surface SF of the second via insulating layer VIA2 may be substantially flat, the thickness of the second via insulating layer VIA2 may not be uniform.

The light emitting element LE may be disposed on a portion of the second via insulating layer VIA2. The light emitting element LE may include a pixel electrode PE, a light emitting layer EL, and a common electrode CE.

The pixel electrode PE may be disposed on the second via insulating layer VIA2. The pixel electrode PE may include a first pixel electrode PE1 disposed on the second via insulating layer VIA2, a second pixel electrode PE2 disposed on the first pixel electrode PE1, and a third pixel electrode PE3 disposed on the second pixel electrode PE2, in order along the thickness direction.

The pixel electrode PE may be disposed along a profile of the upper surface SF of the second via insulating layer VIA2. That is, an upper surface of the pixel electrode PE may be substantially flat. The upper surface of the pixel electrode PE may not have a step difference, and a level of the upper surface of the pixel electrode PE may be substantially constant.

The pixel defining layer PDL may be disposed on the second via insulating layer VIA2 and the pixel electrode PE, and may expose at least a portion of the pixel electrode PE to outside the pixel defining layer PDL.

The light emitting layer EL may be disposed on the pixel electrode PE exposed by the pixel defining layer PDL. As the upper surface SF of the second via insulating layer VIA2 and the upper surface of the pixel electrode PE may be substantially flat, a thickness of the light emitting layer EL may be substantially constant. Here, the thickness of the light emitting layer EL may be a length of the light emitting layer EL in the third direction D3. In an embodiment, the light emitting layer EL may include a quantum dot.

The common electrode CE may be disposed on the pixel defining layer PDL and the light emitting layer EL, and the encapsulation layer TFE may be disposed on the common electrode CE.

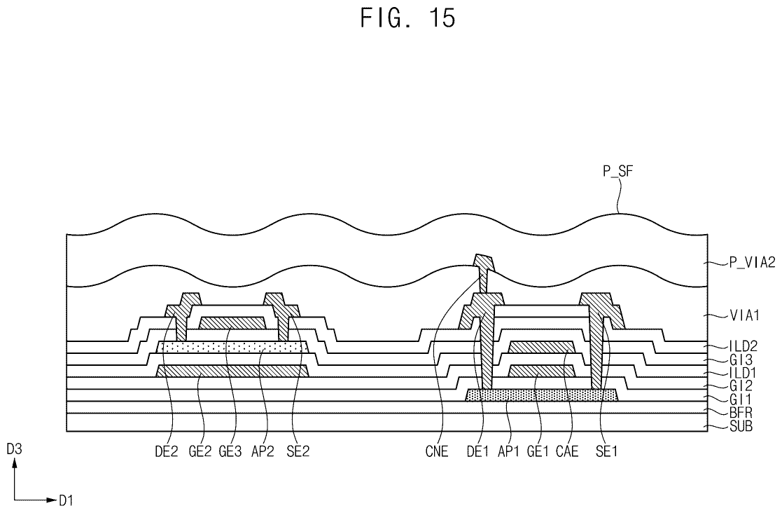

FIGS. 15, 16, and 17 are cross-sectional views illustrating a method of manufacturing the display device 20 of FIG. 13.

A method of manufacturing a display device 20 described with reference to FIGS. 15, 16, and 17 may be a method of manufacturing the display device 20 described with reference to FIGS. 13 and 14. Accordingly, redundant descriptions will be omitted or simplified.

Referring to FIG. 15, the buffer layer BFR, the first active pattern AP1, the first gate insulating layer GI1, the first gate layer, the second gate insulating layer GI2, the second gate layer, the first interlayer insulating layer ILD1, the second active pattern AP2, the third gate insulating layer GI3, the third gate layer, the second interlayer insulating layer ILD2, the first conductive layer, the first via insulating layer VIA1, and the second conductive layer may be sequentially formed on the substrate SUB.

A preliminary second via insulating layer P_VIA2 may be formed on the first via insulating layer VIA1 and the second conductive layer. The preliminary second via insulating layer P_VIA2 may cover the second conductive layer. The preliminary second via insulating layer P_VIA2 may be formed along the profile of the first via insulating layer VIA1. That is, a preliminary upper surface P_SF of the preliminary second via insulating layer P_VIA2 may not be substantially flat. The preliminary upper surface P_SF of the preliminary second via insulating layer P_VIA2 may have a step difference, and a level of the preliminary upper surface P_SF of the preliminary second via insulating layer P_VIA2 may not be substantially constant.

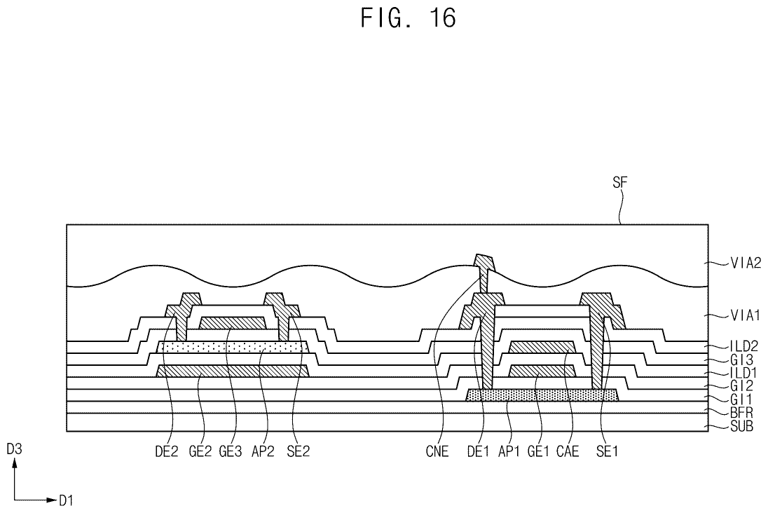

Referring to FIGS. 15 and 16, the preliminary upper surface P_SF of the preliminary second via insulating layer P_VIA2 may be planarized such as by polishing to form the second via insulating layer VIA2.

As the preliminary upper surface P_SF of the preliminary second via insulating layer P_VIA2 may be polished, the planarized upper surface SF of the second via insulating layer VIA2 may be substantially flat. That is, the planarized upper surface SF of the second via insulating layer VIA2 may not have a step difference, and the level of the planarized upper surface SF of the second via insulating layer VIA2 may be substantially constant.

For example, the preliminary upper surface P_SF of the preliminary second via insulating layer P_VIA2 may be polished through a chemical mechanical polishing process. In addition, the polishing process may be performed using a zirconia slurry, but the present disclosure is not limited thereto.

In an embodiment, the thickness of the second via insulating layer VIA2 may not be constant at positions along the first via insulating layer VIA1. That is, as the lower surface of the second via insulating layer VIA2 may be formed along the profile of the first via insulating layer VIA1 and the planarized upper surface SF of the second via insulating layer VIA2 may be formed to be substantially flat through the polishing process, the thickness of the second via insulating layer VIA2 may not be uniform.

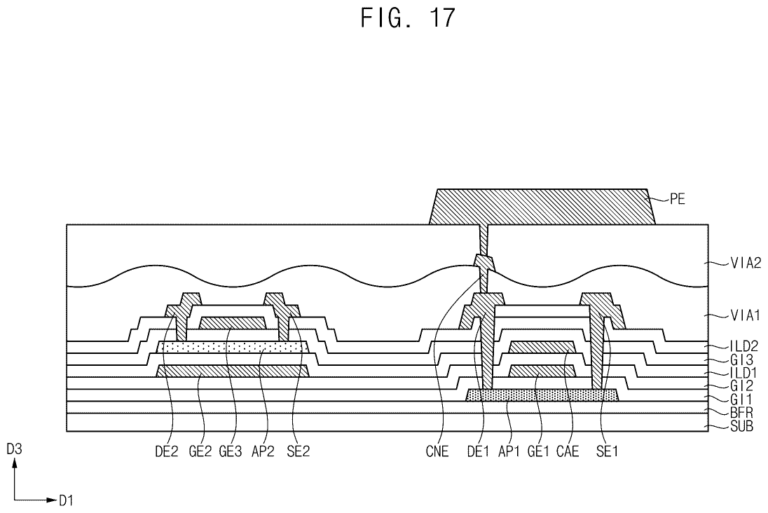

Referring to FIGS. 16 and 17, the pixel electrode PE may be formed on the second via insulating layer VIA2. The pixel electrode PE may be disposed along the profile of the planarized upper surface SF of the second via insulating layer VIA2. That is, the upper surface of the pixel electrode PE may be substantially flat owing to the planarized upper surface SF of the second via insulating layer VIA2 along which a material layer for forming the pixel electrode PE is provided.

Referring back to FIG. 13, the pixel defining layer PDL, the light emitting layer EL, the common electrode CE, and the encapsulation layer TFE may be sequentially formed on the pixel electrode PE.

In an embodiment, the light emitting layer EL may be formed through an inkjet process. In this case, as the planarized upper surface SF of the second via insulating layer VIA2 and the upper surface of the pixel electrode PE may be substantially flat, the thickness of the light emitting layer EL may be substantially constant.

The display device 20 according to an embodiment of the present disclosure may include the second via insulating layer VIA2 whose planarized upper surface SF is polished to be substantially flat. As the thickness of the light emitting layer EL disposed on the second via insulating layer VIA2 may be substantially uniform without having a step difference, luminous efficiency and luminance uniformity of the light emitting element LE may be improved. Accordingly, display quality of the display device 20 may be improved.

The display devices 10 and 20 according to embodiments of the present disclosure may be applied to various electronic devices. An electronic device according to an embodiment of the present disclosure may include the display device 10 or the display device 20 described above, and may further include a module or device having additional functions in addition to the display device 10 or the display device 20.

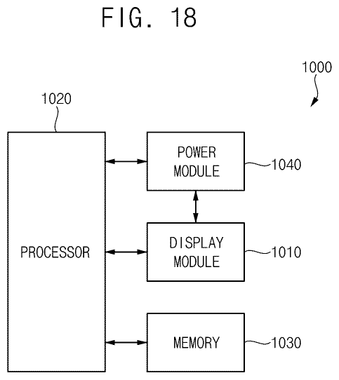

FIG. 18 is a block diagram illustrating an electronic device according to an embodiment of the present disclosure.

Referring to FIG. 18, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

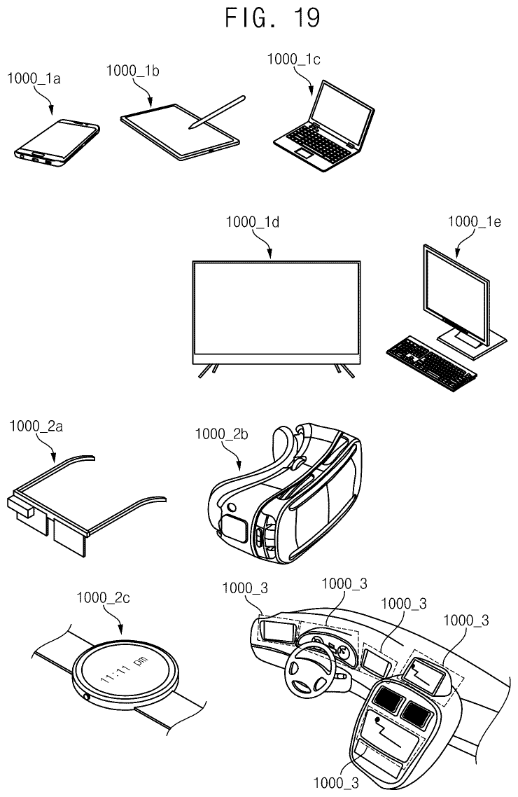

FIG. 19 is a schematic view of electronic devices according to embodiments of the present disclosure.

Referring to FIG. 19, various electronic devices to which the display device according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate;
a via insulating layer on the substrate;
a pixel electrode of a light emitting element, on the via insulating layer, the pixel electrode including in order from the via insulating layer:
a first pixel electrode layer;
a second pixel electrode layer having an upper surface which is flat; and
a third pixel electrode layer.

2. The display device of claim 1, wherein within the pixel electrode,
the first pixel electrode layer has an uneven upper surface in a direction along the first pixel electrode layer, and
a thickness of the second pixel electrode layer is not constant in the direction along the first pixel electrode layer.

3. The display device of claim 1, wherein the upper surface of the second pixel electrode layer which is flat is a polished surface.

4. The display device of claim 1, wherein an upper surface of the via insulating layer is a polished surface which is flat.

5. The display device of claim 4, wherein at a location overlapping the pixel electrode, the via insulating layer includes:
a first via insulating layer defining an uneven upper surface;
a second via insulating layer which is between the substrate and the first pixel electrode layer, closer to the pixel electrode than the first via insulating layer and has an upper surface which is flat; and
a thickness of the second via insulating layer which is not constant in a direction along the pixel electrode.

6. The display device of claim 1, further comprising:
a quantum dot light emitting layer of the light emitting element which is on the third pixel electrode layer.

7. The display device of claim 1, further comprising:
an image display layer including the light emitting element; and
a pixel circuit layer connected to the image display layer and including:
a first active pattern on the substrate; and
a second active pattern on the substrate, spaced apart from the first active pattern, and including a material different from a material of the first active pattern.

8. A method of providing a display device, the method comprising:
providing a via insulating layer on a substrate; and
providing a pixel electrode of a light emitting element, on the via insulating layer, the providing of the pixel electrode including:
providing a first pixel electrode layer on the via insulating layer;
providing a second pixel electrode layer having an upper surface which is flat, on the first pixel electrode layer; and
providing a third pixel electrode layer on the second pixel electrode layer.

9. The method of claim 8, wherein the providing of the second pixel electrode layer includes:
providing a preliminary second pixel electrode layer having an uneven upper surface, on the first pixel electrode layer; and
polishing the uneven upper surface of the preliminary second pixel electrode layer to provide the upper surface of the second pixel electrode layer which is flat.

10. The method of claim 9, wherein the polishing of the uneven upper surface of the preliminary second pixel electrode layer includes chemical mechanical polishing.

11. The method of claim 9, wherein the polishing of the uneven upper surface of the preliminary second pixel electrode layer includes using a zirconia slurry.

12. The method of claim 9, wherein
within the uneven upper surface:
a maximum level of the uneven upper surface is furthest from the substrate; and
a minimum level of the uneven upper surface is closest to the substrate and spaced apart from the maximum level by a difference along a thickness direction of the pixel electrode; and
in the providing of the second pixel electrode layer, the uneven upper surface of the preliminary second pixel electrode layer is polished to remove a thickness portion of the preliminary second pixel electrode layer corresponding to the difference.

13. The method of claim 12, wherein the difference by which the minimum level of the uneven upper surface is spaced apart from the maximum level is about 100 angstroms to about 5000 angstroms.

14. The method of claim 8, wherein the providing of the second pixel electrode layer which is on the first pixel electrode layer and has the upper surface which is flat defines a thickness of the second pixel electrode layer which is not constant in a direction along the first pixel electrode layer.

15. The method of claim 8, after the providing of the third pixel electrode layer, further comprising:
patterning the first pixel electrode layer, the second pixel electrode layer and the third pixel electrode layer to provide the pixel electrode of the light emitting element; and
providing a light emitting layer of the light emitting element on the pixel electrode.

16. The method of claim 15, wherein the providing of the light emitting layer includes an inkjet process.

17. The method of claim 15, wherein the light emitting layer includes a quantum dot.

18. The method of claim 8, wherein the providing of the via insulating layer includes:
providing a preliminary via insulating layer having an uneven upper surface, on the substrate; and
polishing the uneven upper surface of the preliminary via insulating layer to provide the via insulating layer having an upper surface which is flat.

19. The method of claim 18, wherein the providing of the via insulating layer further includes:
providing a first via insulating layer defining an uneven upper surface, on the substrate;
providing a second via insulating layer having an uneven upper surface corresponding to the uneven upper surface of the first via insulating layer; and
polishing the uneven upper surface of the second via insulating layer to provide the second via insulating layer having a thickness which is not constant and the via insulating layer having the upper surface which is flat.

20. The method of claim 8, further comprising:
providing an image display layer including the light emitting element, on the substrate; and
providing a pixel circuit layer connected to the image display layer, including:
providing a first active pattern on the substrate; and
providing a second active pattern spaced apart from the first active pattern and including a material different from a material of the first active pattern on the substrate.

21. An electronic device, comprising:
a display device; and
a power module that supplies power to the display device,
wherein the display device includes:
a substrate;
a via insulating layer on the substrate;
a pixel electrode of a light emitting element, on the via insulating layer, the pixel electrode including in order from the via insulating layer:
a first pixel electrode layer;
a second pixel electrode layer having an upper surface which is flat; and
a third pixel electrode layer.
